(19) United States
(12) Patent Application Publication
(10) Pub. No.: US 2023/0232585 A1
(43) Pub. Date: Jul. 20, 2023

(54) LIQUID DEFLECTOR FOR TWO-PHASE IMMERSION COOLING SYSTEM

(71) Applicant: LIQUIDSTACK HOLDING B.V., Amsterdam (NL)

(72) Inventors: Kar-Wing Lau, Hong Kong (HK); Wai Sing Cheng, Hong Kong (HK); Joseph Capes, Northborough, MA (US)

(21) Appl. No.: 18/098,090

(22) Filed: Jan. 17, 2023

Related U.S. Application Data
(60) Provisional application No. 63/299,961, filed on Jan. 15, 2022.

(51) Int. Cl. H05K 7/20

(52) U.S. Cl. CPC H05K 7/203; H05K 7/20318; H05K 7/20327

(57) ABSTRACT

A two-phase immersion cooling system may include an immersion tank configured to receive a dielectric fluid. The immersion tank may have an interior volume including a lower portion and an upper portion. The immersion tank may have an electronic device region configured to receive one or more electronic devices. The system may include a condenser mounted in the upper portion of the immersion tank. The system may include a liquid deflector located in the upper portion of the immersion tank and at least partially between a top side of the electronic device region and a top side of the condenser. The liquid deflector may be configured to prevent or inhibit dielectric liquid from splashing from the electronic device region onto the condenser. Other examples may be claimed or described.

### CROSS-REFERENCE TO RELATED APPLICATION

This application claims priority to U.S. Patent Application No. 63/299,961, filed on Jan. 15, 2022, which is hereby incorporated by reference in its entirety.

### TECHNICAL FIELD

The present disclosure relates to immersion cooling systems and, more specifically, to liquid deflectors for two-phase immersion cooling systems.

### BACKGROUND

Data centers house information technology (IT) equipment for the purposes of storing, processing, and disseminating data and applications. IT equipment may include electronic devices, such as servers, storage systems, power distribution units, routers, switches, and firewalls.

IT equipment consumes electricity and produces waste heat as a byproduct. A data center with many servers may require a dedicated IT cooling system to manage the waste heat. If the waste heat is not removed from the data center, ambient temperature within the data center may rise above an acceptable threshold and temperature-induced performance throttling of electronic devices (e.g., microprocessors) may occur, which is undesirable.

Direct liquid cooling systems can be used to capture waste heat from IT equipment. One form of direct liquid cooling is immersion cooling. In an immersion cooling system, an electronic device is immersed in a dielectric fluid. Waste heat from the electronic device is transferred to the dielectric fluid and then rejected outside the data center through a heat rejection system.

Examples of immersion cooling systems include single-phase immersion cooling systems and two-phase immersion cooling systems. Single-phase immersion cooling systems rely on sensible heat transfer to remove heat from the IT equipment. Two-phase immersion cooling systems leverage both sensible and latent heat transfer to remove heat from the IT equipment.

### SUMMARY

In one aspect, a two-phase immersion cooling system may include an immersion tank configured to receive a dielectric fluid. The immersion tank may have an interior volume having a lower portion and an upper portion. The interior volume may include an electronic device region configured to receive one or more electronic devices. The system may include a condenser mounted in the upper portion of the immersion tank. The system may include a liquid deflector located in the upper portion of the immersion tank and at least partially between a top side of the electronic device region and a top side of the condenser. The liquid deflector may be mounted to the immersion tank. The liquid deflector may be mounted to the condenser. The liquid deflector may be mounted to a chassis that contains or is configured to receive an electronic device. The liquid deflector may have a deflector surface having a plurality of perforations. The liquid deflector may have a cable management opening. The liquid deflector may have an internal fluid passageway fluidly connected to the condenser. The system may include a coolant supply line fluidly connecting the condenser to an inlet of the internal fluid passageway and a coolant return line fluidly connecting an outlet of the internal fluid passageway to the condenser.

In another aspect, a two-phase immersion cooling system may include an immersion tank configured to receive a dielectric fluid. The immersion tank may have an interior volume. The interior volume may include an electronic device region. The electronic device region may be configured to receive one or more electronic devices. The system may include a condenser mounted in a headspace of the immersion tank. The interior volume may include a gap region between the electronic device region and the condenser. A liquid deflector may be located at least partially in the gap region. 9. The liquid deflector may be mounted to an interior surface of the immersion tank. The liquid deflector may be mounted to the condenser. The liquid deflector may be mounted to a chassis that contains or is configured to receive an electronic device. The liquid deflector may include a deflector surface having a plurality of perforations. The liquid deflector may include a cable management opening. The liquid deflector may include an internal fluid passageway fluidly connected to the condenser. The system may include a coolant supply line fluidly connecting the condenser to an inlet of the internal fluid passageway and a coolant return line fluidly connecting an outlet of the internal fluid passageway to the condenser.

In another aspect, a two-phase immersion cooling system may include an immersion tank having an interior volume and a target liquid level. The system may include a condenser mounted above the target liquid level. The interior volume may include an electronic device region. The electronic device region may extend below the target liquid level and above the target liquid level. The system may include a liquid deflector mounted above the target liquid level. The liquid deflector may intersect a liquid pathway extending from the electronic device region to a top surface of the condenser. The liquid deflector may be mounted to the immersion tank. The liquid deflector may be mounted to the condenser. The liquid deflector may include a deflector surface having a plurality of perforations. The liquid deflector may include a cable management opening. The liquid deflector may have an internal fluid passageway having an inlet and an outlet. The system may include a coolant supply line fluidly connecting the condenser to the inlet of the internal fluid passageway and a coolant return line fluidly connecting the outlet of the internal fluid passageway to the condenser.

This Summary is provided to introduce a selection of concepts in a simplified form that are further described below in the Detailed Description. This Summary is not intended to identify key features or essential features of the claimed subject matter, nor is it intended to be used to determine the scope of the claimed subject matter.

### BRIEF DESCRIPTION OF DRAWINGS

In the drawings, like reference characters generally refer to the same parts throughout the different views. Also, the drawings are not necessarily to scale, emphasis instead being placed upon illustrating principles of the invention. In the following description, various embodiments are described with reference to the following drawings, in which:

FIG. 1 shows a semi-transparent perspective view of an immersion cooling system with a liquid deflector shielding a condenser.

FIG. 2 shows a cross-sectional side view of the immersion cooling system of FIG. 1 during operation where the liquid deflector is shielding the condenser from dielectric liquid projected from a server chassis toward the condenser.

FIG. 3A shows the immersion cooling system of FIG. 1 with a second embodiment of a liquid deflector with a cable management opening.

FIG. 3B shows an enlarged view of the liquid deflector of FIG. 3A

FIG. 4 shows the embodiment of FIG. 3 without an immersion tank and with an electronic device cable routed through the cable management opening.

FIG. 5A shows the immersion cooling system of FIG. 1 with a third embodiment of a liquid deflector attached to the condenser.

FIG. 5B shows an enlarged view of the liquid deflector and condenser of FIG. 5A revealing an internal fluid passageway in the liquid deflector.

### DETAILED DESCRIPTION

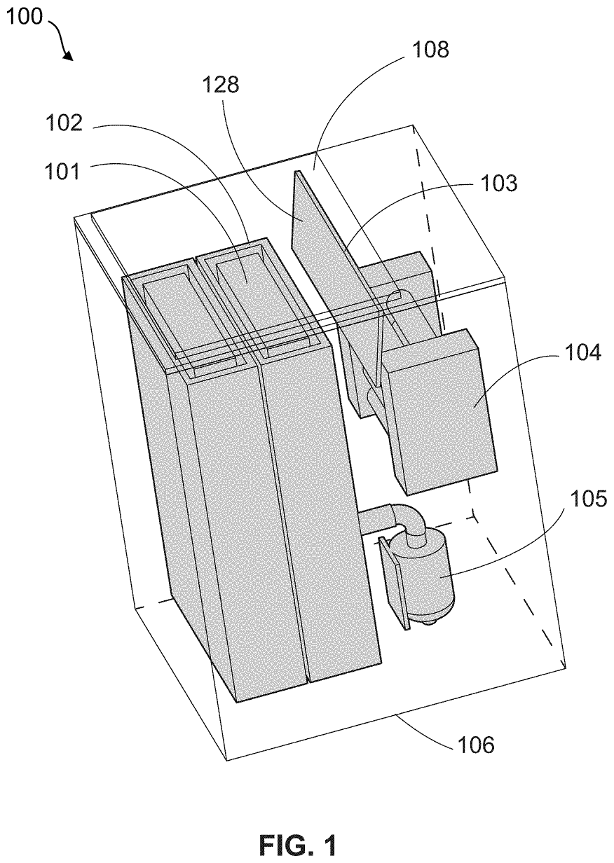

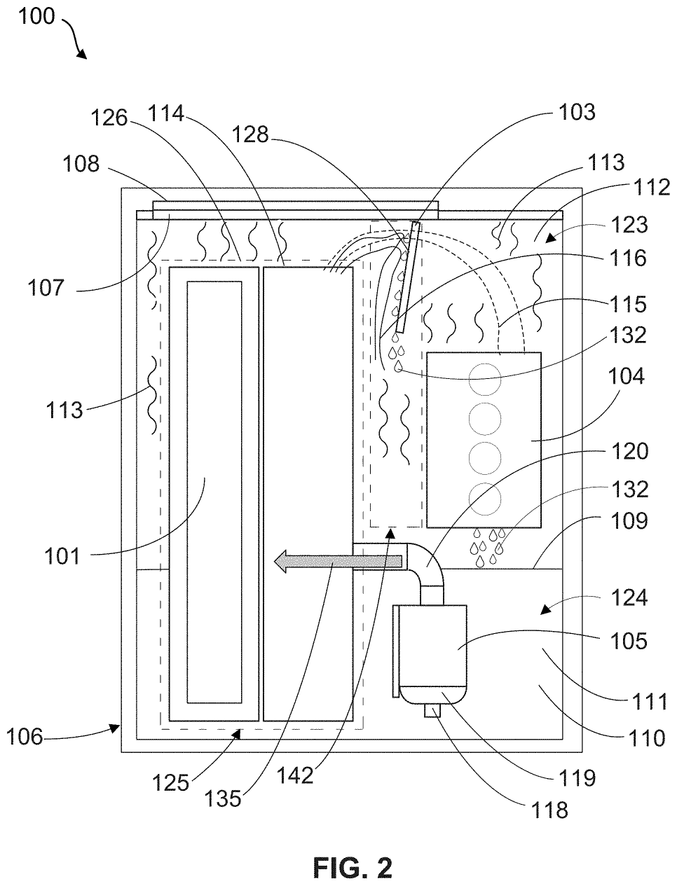

FIG. 1 shows an immersion cooling system 100. The immersion cooling system 100 may include an immersion tank 106. The immersion tank 106 may have an interior volume having an upper portion 123 and a lower portion 124. The immersion tank 106 may include an opening 107 covered by a lid 108, as shown in FIG. 2. The opening 107 may be located at or near the upper portion 123 of the immersion tank 106 and provide access to the interior volume of the immersion tank.

As shown in FIGS. 1 and 2, the immersion tank 106 may be configured to receive one or more electronic devices 101, such as one or more computer servers 101 or network communication devices in an interior volume of the immersion tank 106. Each electronic device 101 may include heat dissipating components, such as processors, memory, and/or power supplies. The electronic devices 101 may be arranged in substantially upright orientations and adjacent to each other to form a stack, to efficiently utilize available interior volume in the immersion tank 106.

As shown in FIG. 2, the immersion cooling system 100 may be configured to operate as a two-phase immersion cooling system 100. The immersion tank 106 may be partially filled with dielectric fluid in liquid phase 110 (referred to herein as “dielectic liquid”). The electronic devices 101 may be partially immersed in the fluid bath 111. The electronic devices 101 may include microprocessors and other heat-dissipating components (e.g., memory, power supply, etc.).

In a conventional two-phase cooling system, an electronic device is fully immersed in a fluid bath to ensure that the entire device is adequately cooled. However, dielectric fluid can be costly, and fully immersing the entire electronic device requires filling the immersion tank so that a liquid level is at or above a top surface of the electronic device. By contrast, the immersion cooling systems 100 described herein are configured to operate with a liquid level 109 that is less than a height of the electronic device, which significantly reduces the quantity and cost of fluid required to operate the system 100. As shown in FIG. 2, the liquid level 109 is lower in the immersion tank than a top surface of the electronic devices 101. In one example, the liquid level 109 may have a height that is less than half of a height of the electronic device 101. In another example, the liquid level 109 may have a height that is less than one-third of a height of the electronic device 101.

A target liquid level may be defined as a dielectric liquid level that is suitable for safe and continuous operation of the immersion cooling system 100. In one example, the immersion tank 106 may have a marking or a range of markings on an interior surface of the tank to identify the target liquid level. Prior to operating the immersion cooling system 100, an operator may verify that the actual liquid level 109 satisfies the target liquid level. If the actual liquid level is below the target liquid level, the operator may add fluid to the system until the target liquid level is achieved.

The upper portion 123 of the tank 106 may be defined as an interior volume of the immersion tank 106 that is located above the target liquid level. The lower portion of the tank 106 may be defined as an interior volume of the immersion tank 106 that is located below the target liquid level. Together, the upper portion 123 and lower portion 124 may define the interior volume of the immersion cooling tank 106.

To operate the system 100 with a relatively low liquid level while still adequately cooling the electronic device 101, the system 100 may include a pump 105 that supplies dielectric liquid 110 to an internal volume of a chassis 102 of the electronic device 101, as shown in FIG. 2. The pump 105 may supply dielectric liquid 110 to one or more electronic devices 101, as shown in FIG. 2. The pump 105 may include an inlet 118 located in the fluid bath and adapted to intake dielectric liquid 110. The pump 105 may include an outlet 120 fluidly connected to an internal volume of the chassis 102. The pump 105 may include a filter 119, such as a charcoal filter located between the inlet 118 and the outlet 120 and configured to remove contaminants from the dielectric liquid before it is introduced to the internal volume of the chassis 102.

In the example shown in FIGS. 1 and 2, the chassis 102 may be enclosed on all sides except for a top opening 114. When a flow 135 of dielectric liquid 110 is supplied to the chassis by the pump 105, the liquid may fill the chassis 102 and then spill over a top edge of the chassis and return to the fluid bath 111. The chassis 102 may be an integral part of the electronic device 101 (e.g., a server case). Alternatively, the chassis 102 may be separate pocket-shaped chassis that is mounted in the immersion tank 106 and removably receives the electronic device 101.

During operation of the electronic device 101, localized boiling may occur in the interior volume of the chassis 102 as heat from the electronic device 101 vaporizes dielectric liquid 110 adjacent to heat dissipating components of the electronic device. The localized boiling may produce vapor bubbles that, due to buoyancy, ascend through the dielectric liquid column within the chassis 102. When the electronic device 101 is producing a high heat flux, such as in the case of a fully utilized central processing unit (CPU) or graphics processing unit (GPU), vigorous boiling may occur proximate to the device, and a stream of vapor bubbles may form and rise through the fluid column in the chassis 102. Similar to a full pot of boiling water, droplets of liquid may sputter, splash, and/or shoot outward from the top opening 114 of the chassis 102 as dielectric fluid in vapor phase 113 (referred to herein as “dielectric vapor”) aggressively escapes from the chassis 102 into a headspace 112 of the immersion tank. The dielectric vapor 113 may collect in the headspace.

The system 100 may include a condenser 104 located in the headspace 112 of the immersion tank 106. The condenser 104 may be located above the liquid level 109. The condenser may receive a coolant (e.g., a water-glycol mixture from a facility cooling loop) that is at a temperature below a boiling point of the dielectric vapor 113. The condenser 104 may remove heat from the dielectric vapor 113, thereby causing the vapor to condense and form a condensate 132 that returns to the fluid bath 111 by way of gravity (e.g., by dripping from the condenser 104 as shown in FIG. 2).

The performance of the condenser 104 (i.e., its ability to convert dielectric vapor to dielectric liquid) may be determined, in part, by its available surface area (e.g., of one or more condenser coils 136). If dielectric liquid is covering all or a portion of the surface area of the condenser 104, its available surface area is reduced and, in turn, the performance of the condenser is reduced. Consequently, it is desirable to prevent the dielectric liquid that projects outwardly from the chassis 102 from landing on the condenser 104 and reducing its available surface area and performance.

FIG. 1 shows a first embodiment of a liquid deflector 103 (referred to herein as “deflector”) that may prevent or inhibit dielectric liquid from splashing from the top opening 114 of the chassis 102 and reaching the condenser 104. The deflector 103 may serve to shield the condenser 104 from dielectric liquid while still allowing dielectric vapor to reach the condenser and be condensed. FIG. 2 shows a first pathway 115 of projected dielectric liquid if the deflector 103 is not present. FIG. 2 shows a second pathway 116 of projected dielectric liquid if the deflector 103 is present. The deflector 103 may intersect the first pathway 115 of projected dielectric liquid that extends from the electronic device region 125 to a top surface of the condenser 104, and thereby prevent or inhibit dielectric liquid from being projected from the electronic device region 125 onto the condenser 104. The liquid deflector 103 may be located at least partially between a top side of the electronic device region 125 and a top side of the condenser 104.

The deflector 103 may include a deflector surface 128 configured to block or impede liquid that is projected from the chassis 102 toward the condenser 104. In some examples, the deflector 103 may be a plate or barrier. The deflector 103 may be angled as shown in FIG. 2. The angle of the deflector surface 128 may be adjustable to allow the condensate 132 dripping from the deflector 103 to be directed to a desired direction (e.g., such as away from the condenser 104). The deflector surface may be a solid surface. Alternately, the deflector surface may include perforations, mesh, and/or a membrane configured to allow dielectric vapor to flow through the deflector while preventing or impeding the flow of dielectric liquid.

The electronic devices 101 may be positioned within an electronic device region 125 in the immersion tank 106, as shown in FIG. 2. Unlike conventional immersion cooling systems, the electronic device region 125 described herein may extend above the target liquid level, as well as below the target liquid level. The electronic device region 125 may be defined by the outermost surfaces of the one or more electronic devices 101 in the immersion tank 106. The deflector 103 may be positioned between a top side 126 of the electronic device region 125 and a top side of the condenser 104, as shown in FIG. 2. The deflector 103 may be positioned in a gap region 142 that is located between the electronic device region 125 and the condenser 104, as shown in FIG. 2.

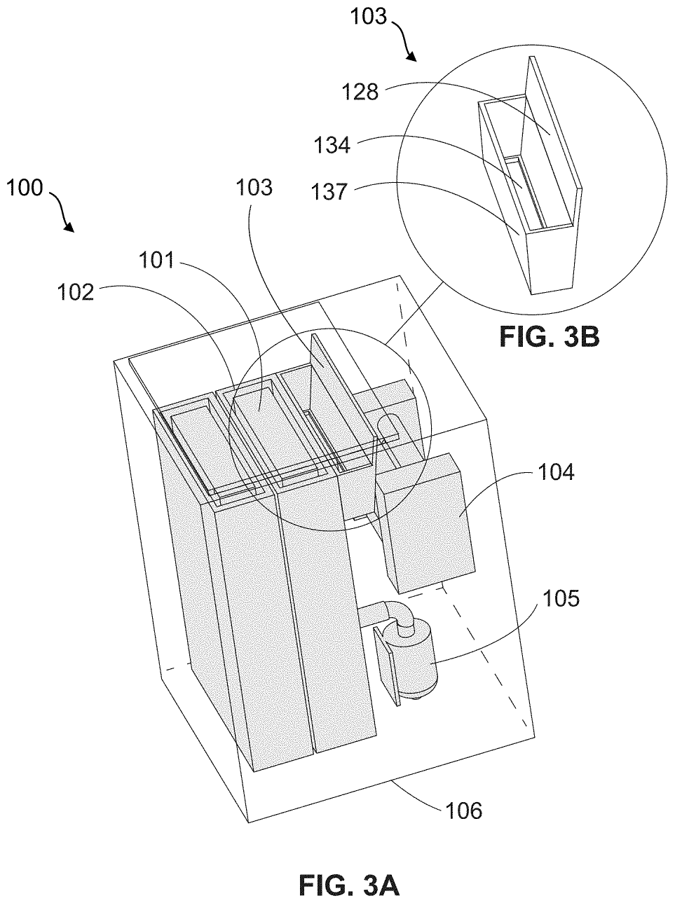

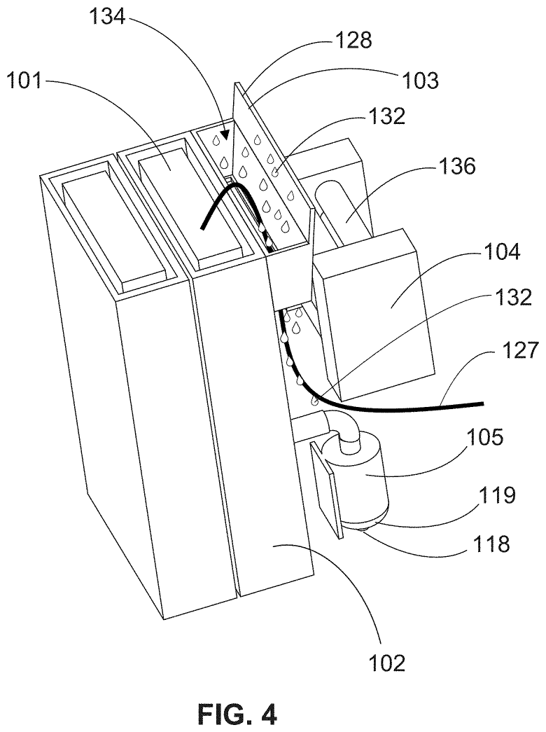

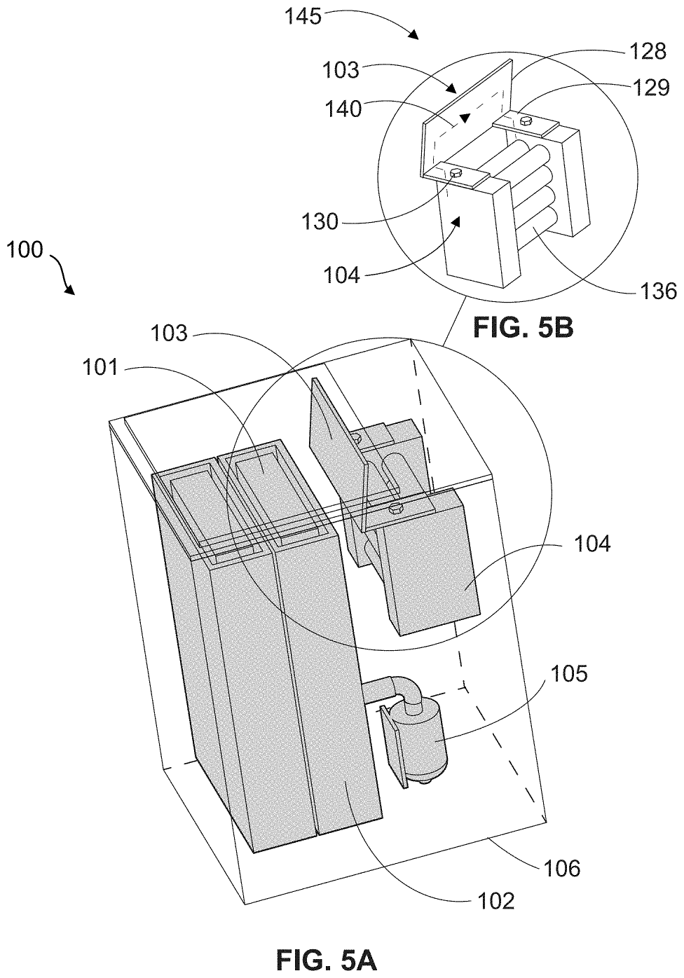

The deflector 103 may be mounted at any suitable location in an interior volume of the immersion tank 106. In the example shown in FIGS. 1 and 2, the deflector 103 may be mounted to a wall (e.g., an interior surface or interior top surface) of the immersion tank 106. In the example shown in FIGS. 3A and 4, the deflector 103 may be mounted to the chassis 102 of the electronic device 101. In the example of FIGS. 5A and 5B, the deflector 103 may be mounted to (e.g., with fasteners), or be an integral part of, the condenser 104.

FIG. 3B shows an enlarged view of the deflector of FIG. 3A. The deflector 103 may include a cable management opening 134. A power or data cable 127 of the electronic device 101 may be routed from a top portion of the electronic device 101 and through the cable management opening 134. The cable management opening 134 may serve to retain a plurality of electrical cables from a plurality of electronic devices in the immersion tank 106. During operation, dielectric vapor 113 may condense and form condensate 132 on the one or more cables. The sides of the deflector 103 may serve to guide the condensate 132 through the cable management opening 134, where it can drip back into the fluid bath 111. The cable management opening 134 may be defined by a plurality of walls 137. The plurality of walls 137 may form an open-bottom sink, as shown in FIG. 3B.

The deflector 103 may include an internal fluid passageway 140, as shown in FIG. 5B. The internal fluid passageway 140 may have an inlet and an outlet. The inlet may be fluidly connected to the condenser 104, and the outlet may be fluidly connected to the condenser 104, thereby providing a flow of coolant through the deflector 103 to cool the deflector and promote condensing of vapor bubbles near the deflector. The coolant supplied to the internal fluid passageway 140 from the condenser 104 may be supplied at a temperature below a boiling point of the dielectric fluid. The deflector 103 may be attached to the condenser 104 to provide a condenser assembly 145, as shown in FIG. 5B. In another example, the deflector 103 may be mounted to the immersion tank 106 or a chassis 102 for an electronic device 101. In these examples, coolant may be supplied to the deflector 103 through a coolant supply line extending between the condenser 104 and the inlet of the internal fluid passageway 140, and coolant may be returned to the condenser 104 by a coolant return line extending from the outlet of the internal passageway 140 to the condenser.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A two-phase immersion cooling system comprising:
an immersion tank configured to receive a dielectric fluid, the immersion tank having an interior volume comprising a lower portion and an upper portion, the immersion tank having an electronic device region configured to receive one or more electronic devices;
a condenser mounted in the upper portion of the immersion tank; and
a liquid deflector located in the upper portion of the immersion tank and at least partially between a top side of the electronic device region and a top side of the condenser.

2. The two-phase immersion cooling system of claim 1, wherein the liquid deflector is mounted to the immersion tank.

3. The two-phase immersion cooling system of claim 1, wherein the liquid deflector is mounted to the condenser.

4. The two-phase immersion cooling system of claim 1, wherein the liquid deflector comprises a deflector surface having a plurality of perforations.

5. The two-phase immersion cooling system of claim 1, wherein the liquid deflector comprises a cable management opening.

6. The two-phase immersion cooling system of claim 1, wherein the liquid deflector comprises an internal fluid passageway fluidly connected to the condenser.

7. The two-phase immersion cooling system of claim 6, further comprising:
a coolant supply line fluidly connecting the condenser to an inlet of the internal fluid passageway; and
a coolant return line fluidly connecting an outlet of the internal fluid passageway to the condenser.

8. A two-phase immersion cooling system comprising:
an immersion tank configured to receive a dielectric fluid, the immersion tank having an interior volume;
an electronic device region located in the interior volume, the electronic device region configured to receive one or more electronic devices;
a condenser mounted in a headspace of the immersion tank;
a gap region located in the interior volume and between the electronic device region and the condenser; and
a liquid deflector located at least partially in the gap region.

9. The two-phase immersion cooling system of claim 8, wherein the liquid deflector is mounted to an interior surface of the immersion tank.

10. The two-phase immersion cooling system of claim 8, wherein the liquid deflector is mounted to the condenser.

11. The two-phase immersion cooling system of claim 8, wherein the liquid deflector comprises a deflector surface having a plurality of perforations.

12. The two-phase immersion cooling system of claim 8, wherein the liquid deflector comprises a cable management opening.

13. The two-phase immersion cooling system of claim 8, wherein the liquid deflector comprises an internal fluid passageway fluidly connected to the condenser.

14. The two-phase immersion cooling system of claim 13, further comprising:
a coolant supply line fluidly connecting the condenser to an inlet of the internal fluid passageway; and
a coolant return line fluidly connecting an outlet of the internal fluid passageway to the condenser.

15. A two-phase immersion cooling system comprising:
an immersion tank having an interior volume and a target liquid level;
a condenser mounted above the target liquid level;
an electronic device region located in the interior volume, the electronic device region extending below the target liquid level and above the target liquid level; and
a liquid deflector mounted above the target liquid level, wherein the liquid deflector intersects a liquid pathway extending from the electronic device region to a top surface of the condenser.

16. The two-phase immersion cooling system of claim 15, wherein the liquid deflector is mounted to the immersion tank.

17. The two-phase immersion cooling system of claim 15, wherein the liquid deflector is mounted to the condenser.

18. The two-phase immersion cooling system of claim 15, wherein the liquid deflector comprises a deflector surface having a plurality of perforations.

19. The two-phase immersion cooling system of claim 15, wherein the liquid deflector comprises a cable management opening.

20. The two-phase immersion cooling system of claim 15, further comprising:
an internal fluid passageway formed in the liquid deflector, the internal fluid passageway having an inlet and an outlet;
a coolant supply line fluidly connecting the condenser to the inlet of the internal fluid passageway; and
a coolant return line fluidly connecting the outlet of the internal fluid passageway to the condenser.
